(19) United States
(12) Patent Application Publication
(10) Pub. No.: US 2006/0189167 A1
(43) Pub. Date: Aug. 24, 2006

(54) Method for fabricating silicon nitride film

(76) Inventors: Hsiang-Ying Wang, Chiai (TW); Neng-Hui Yang, Hsinchu (TW); Huan-Shun Lin, Taichung City (TW)

Correspondence Address: J C PATENTS, INC., 4 VENTURE, SUITE 250, IRVINE, CA, 92618, US

(21) Appl. No.: 11/060,907

(22) Filed: Feb. 18, 2005

(51) Int. Cl. H01L 21/31; H01L 21/44

(52) U.S. Cl. 438/791; 438/664; 438/663

(57) ABSTRACT

A method for fabricating a silicon nitride film is disclosed. The method is adapted for a substrate comprising a transistor device. A self-aligned silicide film is formed over the transistor device. A silicon nitride film is then formed over the substrate. A thermal process is performed to the silicon nitride film. The process temperature of the thermal treatment process is lower than 450° C. and the thermal treatment process is performed under an inert gas environment. According to the fabrication method of the present invention, a high tensile stress silicon nitride film can be formed by a process with a low thermal budget. The electron mobility in the channel region of the transistor device can be enhanced without affecting the thermal stability of metal silicide.

### BACKGROUND OF THE INVENTION

1. Field of the Invention

The present invention relates to a semiconductor process, and more particularly, to a method for fabricating a silicon nitride film with a high tensile stress.

2. Description of the Related Art

Since Metal-Oxide-Semiconductor (MOS) transistors consume low power and have various advantages for high integration, of semiconductor process, MOS transistors become the most important and widely used electronic device. By the enhancement of integration of semiconductor devices, dimensions of MOS transistors must be reduced. The reduction of MOS transistors dimension, however, has limitation. Therefore, other methods, such as increasing channel strain of transistors to improve carrier mobility have been widely studied.

For PMOS transistors, a compressive-strained SiGe film is buried in source/drain regions to enhance hole mobility in channel regions by a selective epitaxial growth process. For NMOS transistors, several methods have been proposed to improve electron mobility in channel regions. These methods usually focus on modifying related film stress, such as the polysilicon layer, the metal silicide film, the silicon nitride cap layer, and the inter-dielectric layer, to enhance the strain of the channel region. It is a well known method that after deposition of a metal silicide film, a silicon nitride film with a tensile stress is covered on the top of the deposited metal silicide film to enhance the tensile strain of the channel region of the NMOS transistor. The increase of the electron mobility of the NMOS transistor is proportional to the strain of the silicon nitride film. In addition, due to the thickness limitation of the silicon nitride film, the stress of the silicon nitride film can dominate the enhancement degree of electron mobility on the NOMS transistor.

Conventionally, the silicon nitride film with a high tensile stress is formed by a Low Pressure Chemical Vapor Deposition (LPCVD) process with a process temperature higher than 600° C. in a furnace. This method, however, affects the thermal stability of the metal silicide film due to the high process temperature. Accordingly, the method described above is not suitable to form the silicon nitride cap layer covering over the metal silicide film.

In recent years, a new method for fabricating a silicon nitride film by using reaction gases, such as bis-tertiary-butylamino-silane (BTBAS), and hexa-chloro-disilane (HCD), has been proposed. The method forms a silicon nitride film by a LPCVD process with a low process temperature. The process temperature to deposit the silicon nitride film usually is higher than 450° C., which is still too high for nickel silicide. The process temperature, therefore, affects the thermal stability of the metal silicide, and as a result increases resistance of the metal silicide.

### SUMMARY OF THE INVENTION

Accordingly, the present invention is directed to a method for fabricating a high tensile stress silicon nitride film by using a low thermal budget process.

Another object of the present invention is also directed to a method for fabricating a silicon nitride film, which method generates high manufacturing yield for silicon nitride films with low costs and simple processes.

According to the objects described above, the present invention provides the method for fabricating a silicon nitride film. The method is adapted for a substrate, and at least one transistor device is formed over the substrate. The method comprises the following steps. First, a self-aligned metal silicide film is formed over the transistor device. Then, a silicon nitride film is formed over the substrate. A thermal treatment process is then performed to the silicon nitride film. Wherein, the process temperature of the thermal treatment process is lower than 450° C., and the thermal treatment process is performed in an inert gas environment.

According to an embodiment of the present invention, in the method for fabricating the silicon nitride film described above, the thermal treatment process can be, for example, a furnace method and is performed under a vacuum situation or a normal pressure. In addition, the step of forming the silicon nitride film over the substrate can be a Plasma Enhanced Chemical Vapor Deposition (PECVD) process, for example. Wherein, the reaction gas used in the PECVD process comprises, for example, silane (SiH₄) and ammonia(NH₃). The process temperature is about lower than 400° C.

The present invention provides another method for fabricating a silicon nitride film. The method comprises the following steps. First, a substrate is provided. A silicon nitride film is formed over the substrate. A thermal treatment process is then performed to the silicon nitride film. Wherein, the process temperature of the thermal treatment process is between 400° C. and 1100° C., and the thermal treatment process is performed in an inert gas environment.

According to an embodiment of the present invention, in the method for fabricating the silicon nitride film described above, the process temperature of the thermal treatment process is between 400° C. and 600° C., between 600° C. and 800° C., or between 800° C. and 1100° C. Wherein, the thermal treatment process can be, for example, a furnace method, and performed under a vacuum situation or a normal pressure. In addition, the step of forming the silicon nitride film over the substrate can be a Plasma Enhanced Chemical Vapor Deposition (PECVD) process, for example. Wherein, the reaction gas used in the PECVD process comprises, for example, silane and ammonia. The process temperature is about lower than 400° C.

The method of fabricating the silicon nitride film according to the present invention can fabricate the silicon nitride film with a high tensile stress by using a low thermal budget process. Without affecting thermal stability of the metal silicide film, the present invention improves electron mobility in the channel of the transistor device by forming the silicon nitride film with a high tensile stress.

In addition, the method for fabricating the silicon nitride film does not require special reaction gases or equipment. Accordingly, the present invention has the advantages of low costs and simple processes.

The present invention forms the silicon nitride film by the PECVD process and the short-time thermal treatment process. Compared with the prior art method for fabricating a silicon nitride film by a LPCVD process in a furnace, the present invention has high manufacturing yield.

The above and other features of the present invention will be better understood from the following detailed description of the preferred embodiments of the invention that is provided in communication with the accompanying drawings.

### BRIEF DESCRIPTION OF THE DRAWINGS

FIGS. 1A and 1B are schematic cross sectional views showing progression of a method for fabricating a silicon nitride film according to an embodiment of the present invention.

FIG. 2 is a configuration showing relationships between tensile stresses of a silicon nitride film and process temperatures of a thermal treatment process.

FIG. 3 is a column configuration showing changes of strengths of the silicon nitride film after the thermal treatment process.

FIG. 4 is a schematic drawing showing a method for fabricating a silicon nitride film according to another embodiment of the present invention.

### DESCRIPTION OF SOME EMBODIMENTS

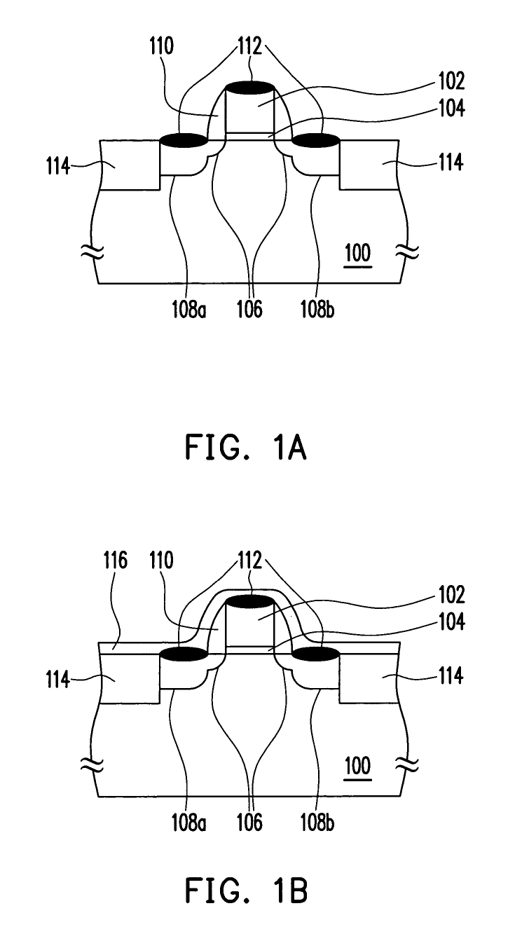

FIGS. 1A and 1B are schematic cross sectional views showing progression of a method for fabricating a silicon nitride film according to an embodiment of the present invention. First, referring to FIG. 1A, a substrate 100 is provided. At least one transistor device fabricated by a normal semiconductor process is formed over the substrate 100. The transistor device is isolated to other transistor device by a device isolation structure 114. Wherein, the transistor device comprise, for example, a gate 102, a gate oxide layer 104, lightly doped regions 106, source/drain regions 108a and 108b, and spacers 110.

Referring to FIG. 1A, self-aligned metal silicide films 112 are formed over the gate 102, and the source/drain regions 108a and 108b. The metal silicide may be titanium silicide, tungsten silicide, cobalt silicide, nickel silicide, molybdenum silicide, or platinum silicide. The method of forming the metal silicide film comprises: first a metal film for forming a metal silicide is deposited over a substrate; an annealing process is performed so that the source/drain regions 108a and 108b, and the gate 102 interact with the metal film to form metal silicide. The un-reacted metal film is then removed.

Referring to FIG. 1B, a silicon nitride film 116 is formed over the substrate 100. The method of forming the silicon nitride film 116 can be, for example, a Plasma Enhanced Chemical Vapor Deposition (PECVD) process. The reaction gas of the PECVD process can be, for example, silane and ammonia, or other suitable reaction gases. Wherein, the process temperature of the PECVD process is preferred lower than 400° C. In a preferred embodiment, the process temperature of the PECVD process is about 350° C., the process pressure is about 2.6 Torr, the flow rate of silane is about 500 sccm, and the flow rate of the ammonia is about 4000 sccm, for example.

Then, a thermal treatment process is performed to the silicon nitride film 116 to improve the tensile stress thereof. Wherein, the thermal treatment process is performed, for example, in a furnace and under an inert gas environment and the thermal treatment process can be under vacuum or normal pressure condition. Note that, in order to prevent damaging the thermal stability of the metal silicide film 112, the process temperature of the thermal treatment process is preferred lower than 450° C. After the thermal treatment process, bonding strengths of Si—H and N—H become weak, and hydrogen atoms are released from the silicon nitride film. It means that the silicon nitride film with the preferred tensile stress is acquired by reducing the amount of hydrogen atoms in the silicon nitride film. In a preferred embodiment, the process temperature of the thermal treatment process described above is about 400° C., the process pressure is about 0.7 Torr, the flow rate of the inert gas, such as nitrogen, is about 100 sccm, and the process time of the thermal treatment process is about 10 minutes.

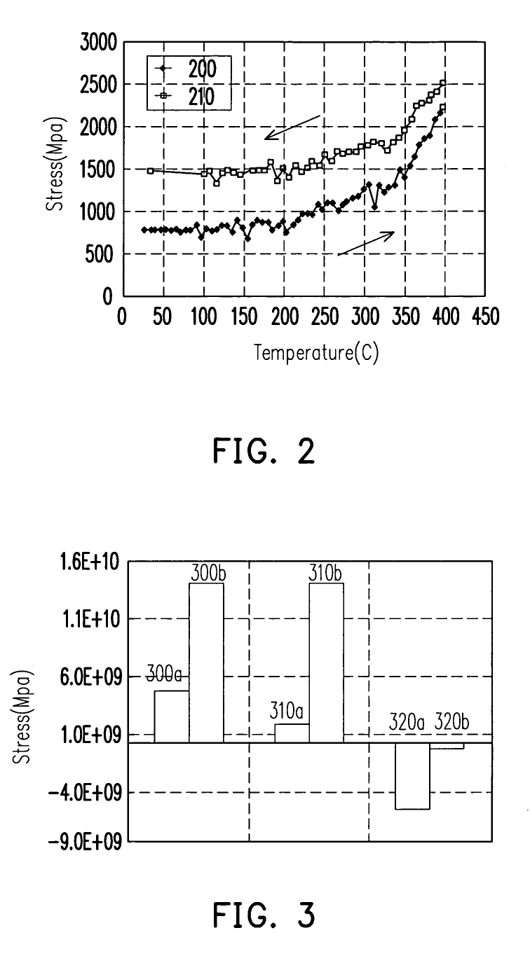

FIG. 2 is a configuration showing the relationship between tensile stresses of a silicon nitride film and process temperatures of a thermal treatment process. Referring to FIG. 2, after the thermal cycle, i.e., the thermal treatment process, by raising the process temperature to 400° C. and cooling down, the tensile stress of the silicon nitride film, such as PE-SiN, formed by the PECVD process varies with the temperature-incline curve 200 and the temperature-decline curve 210. Referring to FIG. 2, by raising the process temperature, the tensile stress of the silicon nitride film also increases. Though in the cooling-down step, the enhanced tensile stress of the silicon nitride film declines slightly, comparing the tensile stresses of the silicon nitride at the beginning of the temperature-incline curve and the end of the temperature-decline curve, the whole tensile stress of the silicon nitride film, after the thermal treatment process, is actually increased.

FIG. 3 is a column configuration showing changes of strengths of the silicon nitride film after the 400° C. thermal treatment process. Referring to FIG. 3, there are three relationships for the silicon nitride films with different strengths, which are the strength 300a of the silicon nitride film with a high tensile stress, the strength 310a of the silicon nitride film with a low tensile stress, and the strength 320a of the silicon nitride film with a compressive strength. These strengths 300a, 310a and 320a represent strengths of the silicon nitride film without the thermal treatment process after deposition process. After the 400° C. thermal treatment process, strengths 300b, 310b and 320b of the silicon nitride film with a tensile stress proves that the thermal treatment process is the key step of improving the tensile stress of the silicon nitride film. It means that, regardless difference of the original tensile stresses of a silicon nitride film with a high tensile stress or with a low tensile stress, the tensile stresses of these silicon nitride films can be, after the above described thermal treatment process, improved and reached a similar value.

In the preferred embodiment described above, in consideration of bad effect to the metal silicide film resulting from a high temperature process, it is preferred that the process temperature of the thermal treatment process is below 450° C. The present invention, however, is not limited thereto. Whenever it is required to form the silicon nitride film with a high tensile stress in the semiconductor process, the method of fabricating the silicon nitride film of the present invention can be used.

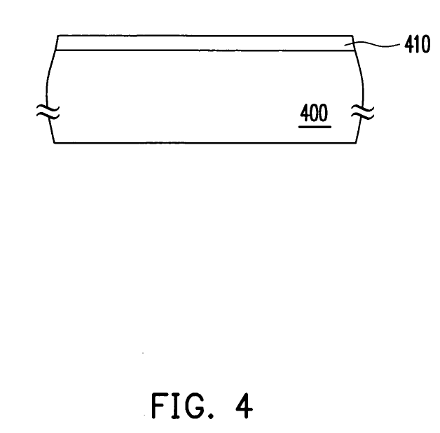

FIG. 4 is a schematic drawing showing a method for fabricating a silicon nitride film according to another embodiment of the present invention. Referring to FIG. 4, a substrate 400 is provided first. Wherein, a semiconductor device (not shown) is formed over the substrate 400. The semiconductor device is not specified, which can be a transistor device or a metal interconnect line.

A silicon nitride film 410 is then formed over the substrate 400. Wherein, the method of forming the silicon nitride film 410 can be, for example, a PECVD process. The reaction gas of the PECVD process comprises, for example, silane and ammonia, or other suitable gases.

A thermal treatment process is performed to the silicon nitride film 410 to improve the tensile stress thereof. Wherein, the thermal treatment process can be performed in a furnace and under an inert gas environment, for example. The process pressure of the thermal treatment process can be under a vacuum situation or a normal pressure. The process temperature of the thermal treatment process of this embodiment can be between 400° C. to 1100° C. Further, to meet different conditions for forming the film, the process temperature of the thermal treatment process described above can be between 400° C. to 600° C., between 600° C. to 800° C., or between 800° C. to 1100° C.

Accordingly, the present invention forms the cap silicon nitride film covering the metal silicide film by using a low-temperature PECVD process. A low-temperature thermal treatment process is used to improve the tensile stress of the silicon nitride film. The silicon nitride film with a high tensile stress thus can be acquired by a process with a low thermal budget. Without affecting the thermal stability of the metal silicide film, electron mobility of electrons in the channel of the transistor device can be improved by enhancing the tensile stress of the silicon nitride film.

In addition, the present invention uses silane and ammonia which are conventionally used as a reaction gas in fabricating the silicon nitride film, and the equipment for depositing the silicon nitride film and the thermal treatment process is commonly used in the industry; accordingly, the method for fabricating the silicon nitride film of the present invention has the advantages of low costs and simple processes.

After the silicon nitride film is formed by the PECVD process, the present invention uses a short-time thermal treatment process to enhance the tensile stress of the silicon nitride film. Compared with the silicon nitride film formed by a LPCVD process in a furnace, the method of the present invention has the advantage of the high manufacturing yield.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A method for fabricating a silicon nitride film adapted for a substrate, wherein at least one transistor device is formed over the substrate, the method comprising:
forming a self-aligned metal silicide film over the transistor device;
forming a silicon nitride film over the substrate; and
performing a thermal treatment process to the silicon nitride, wherein a process temperature of the thermal treatment process is lower than 450° C., and the thermal treatment process is performed in an inert gas environment.

2. The method for fabricating the silicon nitride film of claim 1, wherein the thermal treatment process comprises a furnace process.

3. The method for fabricating the silicon nitride film of claim 1, wherein the inert gas comprises nitrogen gas.

4. The method for fabricating the silicon nitride film of claim 1, wherein the step of forming the silicon nitride film over the substrate comprises a plasma enhanced chemical vapor deposition (PECVD) process.

5. The method for fabricating the silicon nitride film of claim 4, wherein the PECVD process uses a reaction gas comprising silane and ammonia.

6. The method for fabricating the silicon nitride film of claim 4, wherein a process temperature of the PECVD process is lower than 400° C.

7. A method for fabricating a silicon nitride film, comprising the following steps:
providing a substrate;
forming the silicon nitride film over the substrate; and
performing a thermal treatment process, wherein a process temperature of the thermal treatment process is between 400° C. and 1100° C., and the thermal treatment process is performed in an inert gas environment.

8. The method for fabricating the silicon nitride film of claim 7, wherein the process temperature of the thermal treatment process is between 400° C. and 600° C.

9. The method for fabricating the silicon nitride film of claim 7, wherein the process temperature of the thermal treatment process is between 600° C. and 800° C.

10. The method for fabricating the silicon nitride film of claim 7, wherein the process temperature of the thermal treatment process is between 800° C. and 1100° C.

11. The method for fabricating the silicon nitride film of claim 7, wherein the thermal treatment process comprises a furnace process.

12. The method for fabricating the silicon nitride film of claim 7, wherein the inert gas comprises nitrogen gas.

13. The method for fabricating the silicon nitride film of claim 7, wherein the step of forming the silicon nitride film over the substrate comprises a plasma enhanced chemical vapor deposition (PECVD) process.

14. The method for fabricating the silicon nitride film of claim 13, wherein the PECVD process uses a reaction gas comprising silane and ammonia.

15. The method for fabricating the silicon nitride film of claim 13, wherein the process temperature of the PECVD process is lower than 400° C.
